(19) United States
(12) Patent Application Publication
(10) Pub. No.: US 2011/0006293 A1
(43) Pub. Date: Jan. 13, 2011

(54) DEVICES DERIVED FROM ELECTRICALLY CONDUCTIVE POLYMERS

(75) Inventors: Che-Hsiung Hsu, Wilmington, DE (US); Kim Sunghan, Goleta, CA (US); Nora Sabina Radu, Landenberg, PA (US); William J. Gambogi, Cape May, NJ (US)

Correspondence Address: WOODCOCK WASHBURN LLP, CIRA CENTRE, 12TH FLOOR, 2929 ARCH STREET, PHILADELPHIA, PA, 19104-2891, US

(73) Assignee: E. I. DU PONT DE NEMOURS AND COMPANY, Wilmington, DE (US)

(21) Appl. No.: 12/887,885

(22) Filed: Sep. 22, 2010

Related U.S. Application Data
(62) Division of application No. 11/794,369, filed on Jan. 29, 2008, now abandoned.
(60) Provisional application No. 60/640,324, filed on Dec. 30, 2004.
(60) Provisional application No. 60/640,961, filed on Dec. 30, 2004.
(60) Provisional application No. 60/694,917, filed on Jun. 28, 2005.
(60) Provisional application No. 60/694,915, filed on Jun. 28, 2005.

(51) Int. Cl. H01L 51/50; H01B 1/12; B32B 27/08

(52) U.S. Cl. 257/40; 252/500; 428/413; 257/E51.018

(57) ABSTRACT

Organic electronic devices derived from electrically conductive polymer compositions having a pH greater than 1.8 and a hole transporting material are described.

### CROSS REFERENCE TO RELATED APPLICATIONS

This application claims is a divisional application from U.S. patent application Ser. No. 11/794,369, filed Jan. 29, 2008, which is the National Stage Entry of PCT/US05/47413, filed Dec. 29, 2005, which claims benefit to U.S. Provisional Application Ser. Nos. 60/640,324 and 60/640,961, filed Dec. 30, 2004, and Ser. Nos. 60/694,917 and 60/694,915, filed Jun. 28, 2005, the disclosures of which are each incorporated herein by reference in their entireties.

### FIELD

This invention relates in general to organic electronic devices derived from electrically conductive polymers, hole transport materials and light emitting materials, and methods for fabrication of organic electronic devices.

### BACKGROUND

Organic electronic devices convert electrical energy into radiation, detect signals through electronic processes, convert radiation into electrical energy, or include one or more organic semiconductor layers. In some layers of an organic electronic device, electrically conductive polymers are extremely useful, as is appreciated by those skilled in the art. Organic electronic devices include organic light emitting diodes (OLEDs), which use either polymers or small molecules as light emitting materials. The small molecules comprise organic compounds and organometallic complexes, which are either fluorescent or phosphorescent light emitting materials and well known in the art.

Conventional electrically conductive polymers (ECPs) using water soluble non-fluorinated polymeric acids as counter anions are known to be useful as a buffer layer material. However, conventional ECPs are very acidic, having pH below 1.8. This extreme acidity attacks both the anode layer and processing equipment. Moreover, low pH can contribute to decreased stress life of an organic device.

Thus, improved ECPs are needed.

### SUMMARY

In some embodiments, the present invention provides electrically conductive polymer (ECP) compositions having a pH greater than 1.8, as well as devices, compositions, and methods employing the same.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 is a schematic diagram of an organic electronic device.

The figures are provided by way of example and are not intended to limit the invention. Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

In one embodiment, the present invention provides an electrically conductive polymer (ECP) composition comprising an electrically conductive polymer in a liquid medium, wherein the composition has a pH greater than 1.8. As used herein, the term “electrically conductive polymer” refers to any polymer or oligomer which is inherently or intrinsically capable of electrical conductivity without the addition of carbon black or conductive metal particles. In some embodiments, the electrically conductive polymer is conductive in a protonated form and not conductive in an unprotonated form. The term “polymer” encompasses homopolymers and copolymers. The term “electrical conductivity” includes conductive and semi-conductive. In one embodiment, films made from the electrically conductive polymer have a conductivity of at least 10⁻⁷ S/cm. In one embodiment, a conductive material has a bulk conductivity greater than approximately 10⁻⁶ S(Siemens=1/ohm)/. The term “liquid medium” is intended to mean a liquid material, including a pure liquid, a combination of liquids, a solution, a dispersion, a suspension, and an emulsion. Liquid medium is used regardless whether one or more liquids are present. In one embodiment, the liquid medium is an aqueous medium comprising at least 60%, by weight, water. In one embodiment, the ECP is present in the composition in the range of 0.5 to 10% by weight. In one embodiment, the ECP is present in the range of 1 to 3% by weight. ECP compositions generally have an inherent pH of 1.8 or less. For purposes of the present application, the claims include conventional ECP compositions whose pH has been adjusted above their inherent pH. One would not be motivated to do so necessarily, since the modification reduces conductivity. In one embodiment, the ECP composition has a pH greater than 2.0. In one embodiment, the ECP composition has a pH greater than 3.0. In one embodiment, the ECP composition has a pH greater than 3.9. It is understood that all combinations and subcombinations of pH ranges from above 1.8 to above 7 are contemplated.

In some embodiments, the ECP is doped with a water soluble non-fluorinated polymeric acid. The term “doped” is intended to mean that the electrically conductive polymer has a polymeric counterion derived from a polymeric acid to balance the charge on the conductive polymer.

In some embodiments, the ECP is a buffer material. The term “buffer layer” or “buffer material” is intended to mean electrically conductive or semiconductive materials which may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. The term “charge injection,” when referring to a layer, material, member, or structure, is intended to mean such layer, material, member or structure promotes charge migration into an adjacent layer, material, member or structure. The term “charge transport,” when referring to a layer, material, member, or structure is intended to mean such layer, material, member, or structure facilitates migration of such charge through the thickness of such layer, material, member, or structure with relative efficiency and small loss of charge.

In some embodiments, the ECP is selected from the group consisting of polythiophenes, polypyrroles, polyanilines, polycyclic aromatic polymers, copolymers thereof, and mixtures thereof. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring. In some embodiments, the ECP is substituted. Exemplary substituents include, but are not limited to, groups such as alkyl (—R), aryl (—Ar), alkoxy (—OR), hydroxy (—OH), alcohol (—ROH), carboxylate (—RCO₂H or —RCO₂M, M=alkali or alkaline earth metal), and sulfonate (—RSO₃H or —RSO₃M).

In some embodiments, the ECP is polydioxythiophene, polyaniline, polypyrrole, poly(thienothiophenes), their copolymers, or mixtures thereof. For example, polyaniline and polydioxythiophene materials can be prepared by polymerizing aniline or dioxythiophene monomers in aqueous solution in the presence of a water soluble polymeric acid, such as poly(styrenesulfonic acid) (PSS).

In one embodiment, the ECP is poly(3,4-ethyenedioxythiophene) (PEDOT) poly(styrenesulfonate) (PSS) aqueous dispersion (commercially available from H. C. Starck GmbH, Germany, under the tradename BAYTRON-P). In another embodiment, the ECP is polyaniline(PAni)/PSS aqueous commercially available from Ormecon Chemie GmbH &Co., Germany.

Polythiophenes are known conductive polymers and can be selected from polythiophenes described in “Handbook of Oligio- and Polythiophenes”, D. Fichou, Ed., Wiley-VCH, New York (1999); J. Roncali, Chem. Rev., 97, 173 (1997); A. Kraft, A. C. Grimsdale and A. B. Holmes, Angew. Chem., 110, 416 (1998); J. Roncali, J. Mater. Chem., 9, 1875 (1999); J. Roncali, Annu. Rep. Prog. Chem. Sec. C., 95, 47 (1999); A. J. Heeger, Synth. Met., 55-57, 3471 (1993); and G. Kobmehl and G. Schopf, Adv. Polym. Sci., 129, 1 (1996). One of skill in the art will discern the polythiophenes suitable for deposition for the purpose of forming organic electronic devices.

In one embodiment, the ECP is aqueous polypyrrole doped with organic sulfonic acid, for example, aqueous polypyrrole commercially available from Aldrich, St. Louis, Mo. (Catalog #482552). It is understood that the ECP can further include water soluble counter anions.

In one embodiment, there is provided a composition, comprising an electrically conductive polymer as described in any of the above embodiments; and a hole transport material (HTM) in a liquid medium, wherein the composition has a pH greater than 1.8. In one embodiment, the liquid medium is an aqueous medium.

In some embodiments, the hole transport material is N,N′diphenyl-N,N′-bis(3-methylphenyl)-[1,1′-biphenyl]-4,4′-diamine (TPD), N,N′-diphenyl-N,N′-bis(4-vinylphenyl)-[1,1′-biphenyl]-4,4′-diamine (divinyl-p-TPD), 1,1bis[(di-4-tolylamino)phenyl]cyclohexane (TAPC), N,N′bis(4-methylphenyl)-N,N′-bis(4-ethylphenyl)-[1,1′-(3,3′-dimethyl)biphenyl]-4,4′-diamine (ETPD), tetrakis (3-methylphenyl)-N,N,N′,N′-2,5-phenylenediamine (PDA), a-phenyl 4-N,N-diphenylaminostyrene (TPS), p (diethylamino)benzaldehyde diphenylhydrazone (DEH), triphenylamine (TPA), bis[4(N,N-diethylamino)-2-methylphenyl](4-methylphenyl)methane (MPMP), 1 phenyl-3-[p-(diethylamino)styryl]-5-[p-(diethylamino)phenyl] pyrazoline (PPR or DEASP), 1,2 trans-bis(9H-carbazol-9-yl)cyclobutane (DCZB), N,N,N′,N′tetrakis(4-methylphenyl)-(1,1′-biphenyl)-4,4′-diamine (TTB), N,N′-Bis(naphthalen-1-yl)-N,N′-bis-(phenyl)benzidine (α-NPB), 4,4′-N,N′-dicarbazolylbiphenyl (CBP), porphyrinic compounds, polyvinylcarbazole, (phenylmethyl)polysilane, poly(arylamines). In another embodiment, HTM comprises copolymer of fluorene-arylene; e.g., fluorene-carbazole, fluorene/1-(bithiophene), fluorene/3,(2,13-benzothiadiazole), fluorene/2-(N,N′-diphenyl-N,N′-di(3-carboethoxyphenyl)benzidine), and the like. In another embodiment, HTM comprises copolymer of arylamines with conjugated monomers. In another embodiment, the HTM polymers or copolymers comprises crosslinkable segments to render insolubility in the solvents of subsequent layer depositions.

In one embodiment, the HTM is HT-6, HT-12, or HT-25, commercially available from Dow Chemical.

In one embodiment, the HTM is N,N′-diphenyl-N,N′-bis(4-vinylphenyl)-[1,1′-biphenyl]-4,4′-diamine (divinyl-p-TPD).

In another embodiment, the present invention provides a method for making a composition for use in an organic electronic device, comprising providing an electrically conductive polymer in an aqueous dispersion; increasing the pH of the dispersion; and contacting the increased pH electrically conductive polymer with a hole transport material.

In one embodiment, the electrically conductive polymer and the hole transport material are in different discrete layers that are adjacent. In one embodiment, the electrically conductive polymer and the hole transport material are in the same layer.

In another embodiment, the present invention provides a composition comprising the compositions described above and at least one solvent, processing aid, charge transporting material, or charge blocking material.

In another embodiment, the present invention provides an organic electronic device including the composition described above. In one embodiment, the electrically conductive polymer and the hole transport material are in discrete layers. In one embodiment, the electrically conductive polymer and the hole transport material are in the same layer.

In one embodiment, compositions are provided comprising the above-described compounds and at least one solvent, processing aid, charge transporting material, or charge blocking material. These compositions can be in any form, including, but not limited to solvents, emulsions, and colloidal dispersions.

### Device

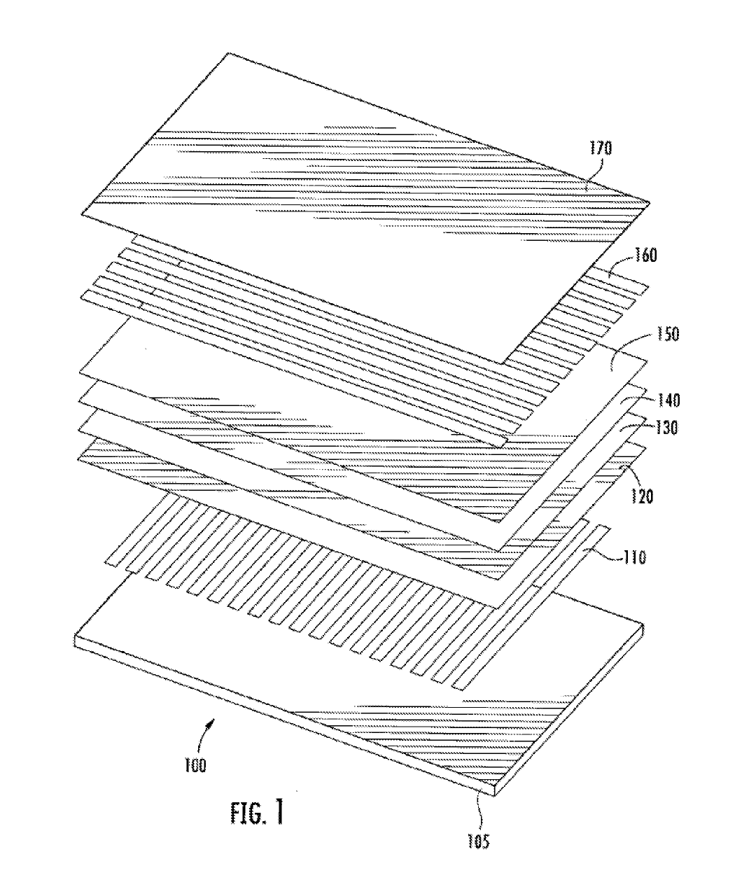

Referring to FIG. 1, an exemplary organic electronic device 100 is shown. The device 100 includes a substrate 105. The substrate 105 may be rigid or flexible, for example, glass, ceramic, metal, or plastic. When voltage is applied, emitted light is visible through the substrate 105.

A first electrical contact layer 110 is deposited on the substrate 105. For illustrative purposes, the layer 110 is an anode layer. Anode layers may be deposited as lines. The anode can be made of, for example, materials containing or comprising metal, mixed metals, alloy, metal oxides or mixed-metal oxide. The anode may comprise a conductive polymer, polymer blend or polymer mixtures. Suitable metals include the Group 11 metals, the metals in Groups 4, 5, and 6, and the Group 8, 10 transition metals. If the anode is to be light-transmitting, mixed-metal oxides of Groups 12, 13 and 14 metals, such as indium-tin-oxide, are generally used. The anode may also comprise an organic material, especially a conductive polymer such as polyaniline, including exemplary materials as described in “Flexible Light-Emitting Diodes Made From Soluble Conducting Polymer,” Nature, Vol. 357, pp 477 479 (11 Jun. 1992). At least one of the anode and cathode should be at least partially transparent to allow the generated light to be observed.

A buffer layer 120 is deposited over the anode layer 110. In one embodiment, the buffer layer is deposited from an ECP composition having a pH greater than 1.8. In one embodiment, the buffer layer is deposited from an ECP composition having a pH greater than 1.8 and further comprising a hole transport material.

An optional layer, comprising hole transport material, may be deposited over the buffer layer 120. Examples of hole transport materials suitable for use as the hole transport material layer have been summarized, for example, in Kirk Othmer Encyclopedia of Chemical Technology, Fourth Edition, Vol. 18, p. 837 860, 1996, by Y. Wang. Both hole transporting “small” molecules as well as oligomers and polymers may be used. Hole transporting molecules include, but are not limited to: N,N′diphenyl-N,N′-bis(3-methylphenyl)-[1,1′-biphenyl]-4,4′-diamine (TPD), 1,1bis[(di-4-tolylamino)phenyl]cyclohexane (TAPC), N,N′bis(4-methylphenyl)-N,N′-bis(4-ethylphenyl)-[1,1′-(3,3′-dimethyl)biphenyl]-4,4′-diamine (ETPD), tetrakis(3-methylphenyl)-N,N,N′,N′-2,5-phenylenediamine (PDA), a-phenyl 4-N,N-diphenylaminostyrene (TPS), p(diethylamino)benzaldehyde diphenylhydrazone (DEH), triphenylamine (TPA), bis[4(N,N-diethylamino)-2-methylphenyl](4-methylphenyl)methane (MPMP), 1phenyl-3-[p-(diethylamino)styryl]-5-[p-(diethylamino)phenyl]pyrazoline (PPR or DEASP), 1,2trans-bis(9H-carbazol-9-yl)cyclobutane (DCZB), N,N,N′,N′tetrakis(4-methylphenyl)-(1,1′-biphenyl)-4,4′-diamine (TTB), N,N′-bis(naphthalen-1-yl)-N,N′-bis-(phenyl)benzidine (α-NPB), 4,4′-N,N′-dicarbazolyl-biphenyl (CBP),and porphyrinic compounds, such as copper phthalocyanine. Useful hole transporting polymers include, but are not limited to, polyvinylcarbazole, (phenylmethyl)polysilane, and polyaniline. HTM co-polymers include, but are not limited to: fluorene-carbazole, fluorene/1-(bithiophene), fluorene/3,(2,13-benzothiadiazole, fluorene/2-(N,N′-diphenyl-N,N′-di(3-carboethoxyphenyl)benzidine), and copolymers of arylamine with conjugated monomers. Conjugated monomer includes, but not limited to: thiophene, fluorene, and carbazole. The HTM polymers or copolymers may comprise crosslinkable segments to render insolubility in the solvents of subsequent layer depositions.

Conductive polymers are useful as a class. It is also possible to obtain hole transporting polymers by doping hole transporting moieties, such as those mentioned above, into polymers such as polystyrenes and polycarbonates.

An organic layer 130 may be deposited over the hole transport material layer when present, or over the first buffer layer 120. In some embodiments, the organic layer 130 may be a number of discrete layers comprising a variety of components. Depending upon the application of the device, the organic layer 130 can be a light-emitting layer that is activated by an applied voltage (such as in a light-emitting diode or light-emitting electrochemical cell), or a layer of material that responds to radiant energy and generates a signal with or without an applied bias voltage (such as in a photodetector).

Other layers in the device can be made of any materials which are known to be useful in such layers upon consideration of the function to be served by such layers.

Any organic electroluminescent (“EL”) material can be used as a photoactive material (e.g., in layer 130). Such materials include, but are not limited to, fluorescent dyes, small molecule organic fluorescent compounds, fluorescent and phosphorescent metal complexes, conjugated polymers, and mixtures thereof. Examples of fluorescent dyes include, but are not limited to, pyrene, perylene, rubrene, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of Iridium with phenylpyridine, phenylquinoline, or phenylpyrimidine ligands as disclosed in Petrov et al., Published PCT Application WO 02/02714, and organometallic complexes described in, for example, published applications US 2001/0019782, EP 1191612, WO 02/15645, and EP 1191614; and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

In one embodiment of the devices of the invention, photoactive material can be an organometallic complex. In another embodiment, the photoactive material is a cyclometalated complex of iridium or platinum. Other useful photoactive materials may be employed as well. Complexes of Iridium with phenylpyridine, phenylquinoline, or phenylpyrimidine ligands have been disclosed as electroluminescent compounds in Petrov et al., Published PCT Application WO 02/02714. Other organometallic complexes have been described in, for example, published applications US 2001/0019782, EP 1191612, WO 02/15645, and EP 1191614. Electroluminescent devices with an active layer of polyvinyl carbazole (PVK) doped with metallic complexes of iridium have been described by Burrows and Thompson in published PCT applications WO 00/70655 and WO 01/41512. Electroluminescent emissive layers comprising a charge carrying host material and a phosphorescent platinum complex have been described by Thompson et al., in U.S. Pat. No. 6,303,238, Bradley et al., in Synth. Met. (2001), 116 (1-3), 379-383, and Campbell et al., in Phys. Rev. B, Vol. 65 085210.

A second electrical contact layer 160 is deposited on the organic layer 130. For illustrative purposes, the layer 160 is a cathode layer.

Cathode layers may be deposited as lines or as a film. The cathode can be any metal or nonmetal having a lower work function than the anode. Exemplary materials for the cathode can include alkali metals, especially lithium, the Group 2 (alkaline earth) metals, the Group 12 metals, including the rare earth elements and lanthanides, and the actinides. Materials such as aluminum, indium, calcium, barium, samarium and magnesium, as well as combinations, can be used. Li-containing and other compounds, such as LiF and Li₂O, may also be deposited between an organic layer and the cathode layer to lower the operating voltage of the system.

An electron transport layer 140 or electron injection layer 150 is optionally disposed adjacent to the cathode, the cathode being sometimes referred to as the “electron-injecting contact layer.”

An encapsulation layer 170 is deposited over the contact layer 160 to prevent entry of undesirable components, such as water and oxygen, into the device 100. Such components can have a deleterious effect on the organic layer 130. In one embodiment, the encapsulation layer 170 is a barrier layer or film.

Though not depicted, it is understood that the device 100 may comprise additional layers. For example, there can be a layer (not shown) between the anode 110 and buffer layer 120 to facilitate positive charge transport and/or band-gap matching of the layers, or to function as a protective layer. Other layers that are known in the art or otherwise may be used. In addition, any of the above-described layers may comprise two or more sub-layers or may form a laminar structure. Alternatively, some or all of anode layer 110, the buffer layer 120, the hole transport layer, the electron transport layers 140 and 150, cathode layer 160, and other layers may be treated, especially surface treated, to increase charge carrier transport efficiency or other physical properties of the devices. The choice of materials for each of the component layers is preferably determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill of in the art.

In one embodiment, the different layers have the following range of thicknesses: anode 110, 500-5000 Å, in one embodiment 1000-2000 Å; buffer layer 120 and hole transport layer, each 50-2000 Å, in one embodiment 200-1000 Å; photoactive layer 130, 10-2000 Å, in one embodiment 100-1000 Å; layers 140 and 150, 5-2000 Å, in one embodiment 100-1000 Å; cathode 160, 200-10000 Å, in one embodiment 300-5000 Å. The location of the electron-hole recombination zone in the device, and thus the emission spectrum of the device, can be affected by the relative thickness of each layer. Thus the thickness of the electron-transport layer should be chosen so that the electron-hole recombination zone is in the light-emitting layer. The desired ratio of layer thicknesses will depend on the exact nature of the materials used.

In operation, a voltage from an appropriate power supply (not depicted) is applied to the device 100. Current therefore passes across the layers of the device 100. Electrons enter the organic polymer layer, releasing photons. In some OLEDs, called active matrix OLED displays, individual deposits of photoactive organic films may be independently excited by the passage of current, leading to individual pixels of light emission. In some OLEDs, called passive matrix OLED displays, deposits of photoactive organic films may be excited by rows and columns of electrical contact layers.

Devices can be prepared employing a variety of techniques. These include, by way of non-limiting exemplification, vapor deposition techniques and liquid deposition. Devices may also be sub-assembled into separate articles of manufacture that can then be combined to form the device.

In one embodiment, the device has the following structure, in order: anode, buffer layer, hole transport layer, photoactive layer, electron transport layer, electron injection layer, cathode. In one embodiment, the device has the following structure, in order: anode, buffer layer, hole transport layer, photoactive layer, hole blocking layer, electron transport layer, electron injection layer, cathode.

In one embodiment, the anode is made of indium tin oxide or indium zinc oxide. In one embodiment, the buffer layer comprises an ECP selected from the group consisting of polythiophenes, polyanilines, polypyrroles, copolymers thereof, and mixtures thereof.

In one embodiment, the hole transport layer comprises polymeric hole transport material. In one embodiment, the hole transport layer is crosslinkable. In one embodiment, the hole transport layer comprises a compound having triarylamine or triarylmethane groups. In one embodiment, the hole transport layer comprises a material selected from the group consisting of TPD, divinyl p-TPD, MPMP, NPB, CBP, and mixtures thereof, as defined above.

In one embodiment, the photoactive layer comprises an electroluminescent metal complex and a host material. The host can be a charge transport material. In one embodiment, the host material is an organometallic complex having a quinoline or 8-hydroxyquinoline ligand. In one embodiment, the electroluminescent complex is present in an amount of at least 1% by weight. In one embodiment, the electroluminescent complex is 2-20% by weight. In one embodiment, the electroluminescent complex is 20-50% by weight. In one embodiment, the electroluminescent complex is 50-80% by weight. In one embodiment, the electroluminescent complex is 80-99% by weight. In one embodiment, the metal complex is a cyclometalated complex of iridium, platinum, rhenium, or osmium. In one embodiment, the photoactive layer further comprises a second host material. The second host can be a charge transport material. In one embodiment, the second host is a hole transport material. In one embodiment, the second host is an electron transport material. In one embodiment, the second host material is a metal complex of a hydroxyaryl-N-heterocycle. In one embodiment, the hydroxyaryl-N-heterocycle is unsubstituted or substituted 8-hydroxyquinoline. In one embodiment, the metal is aluminum. In one embodiment, the second host is a material selected from the group consisting of tris(8-hydroxyquinolinato)aluminum, bis(8-hydroxyquinolinato)(4-phenylphenolato)aluminum, tetrakis(8-hydroxyquinolinato)zirconium, and mixtures thereof. The ratio of the first host to the second host can be 1:100 to 100:1. In one embodiment the ratio is from 1:10 to 10:1. In one embodiment, the ratio is from 1:10 to 1:5. In one embodiment, the ratio is from 1:5 to 1:1. In one embodiment, the ratio is from 1:1 to 5:1. In one embodiment, the ratio is from 5:1 to 5:10.

In one embodiment, the hole blocking layer comprises a metal complex of a hydroxyaryl-N-heterocycle. In one embodiment, the hydroxyaryl-N-heterocycle is unsubstituted or substituted 8-hydroxyquinoline. In one embodiment, the metal is aluminum. In one embodiment, the electron transport layer comprises a material selected from the group consisting of tris(8-hydroxyquinolinato)aluminum, bis(8-hydroxyquinolinato)(4-phenylphenolato)aluminum, tetrakis(8-hydroxyquinolinato)zirconium, and mixtures thereof. In one embodiment, the electron transport layer comprises a metal complex of a hydroxyaryl-N-heterocycle. In one embodiment, the hydroxyaryl-N-heterocycle is unsubstituted or substituted 8-hydroxyquinoline. In one embodiment, the metal is aluminum. In one embodiment, the electron transport layer comprises a material selected from the group consisting of tris(8-hydroxyquinolinato)aluminum, bis(8-hydroxyquinolinato)(4-phenylphenolato)aluminum, tetrakis(8-hydroxyquinolinato)zirconium, and mixtures thereof. In one embodiment, the electron injection layer is BaO, LiF or LiO₂. In one embodiment, the cathode is Al or Ba/Al.

In one embodiment, the device is fabricated by liquid deposition of the buffer layer, the hole transport layer, and the photoactive layer, and by vapor deposition of the hole blocking layer, when present, the electron transport layer, the electron injection layer, and the cathode.

The buffer layer is formed by depositing an ECP composition as described herein. The ECP can be present in the liquid medium in an amount from 0.5 to 10 percent by weight. Other weight percentages of buffer material may be used depending upon the liquid medium. The buffer layer can be applied by any continuous or discontinuous liquid deposition technique. In one embodiment, the buffer layer is applied by spin coating. In one embodiment, the buffer layer is applied by ink jet printing. After liquid deposition, the liquid medium can be removed in air, in an inert atmosphere, or by vacuum, at room temperature or with heating. In one embodiment, the layer is heated to a temperature less than 275° C. In one embodiment, the heating temperature is between 100° C. and 275° C. In one embodiment, the heating temperature is between 100° C. and 120° C. In one embodiment, the heating temperature is between 120° C. and 140° C. In one embodiment, the heating temperature is between 140° C. and 160° C. In one embodiment, the heating temperature is between 160° C. and 180° C. In one embodiment, the heating temperature is between 180° C. and 200° C. In one embodiment, the heating temperature is between 200° C. and 220° C. In one embodiment, the heating temperature is between 190° C. and 220° C. In one embodiment, the heating temperature is between 220° C. and 240° C. In one embodiment, the heating temperature is between 240° C. and 260° C. In one embodiment, the heating temperature is between 260° C. and 275° C. The heating time is dependent upon the temperature, and is generally between 5 and 60 minutes. In one embodiment, the final layer thickness is between 5 and 200 nm. In one embodiment, the final layer thickness is between 5 and 40 nm. In one embodiment, the final layer thickness is between 40 and 80 nm. In one embodiment, the final layer thickness is between 80 and 120 nm. In one embodiment, the final layer thickness is between 120 and 160 nm. In one embodiment, the final layer thickness is between 160 and 200 nm.

The hole transport layer can be deposited from any liquid medium in which it is dissolved or dispersed and from which it will form a film. In one embodiment, the liquid medium consists essentially of one or more organic solvents. In one embodiment, the liquid medium consists essentially of water or water and an organic solvent. In one embodiment the organic solvent is an aromatic solvent. In one embodiment, the organic liquid is selected from chloroform, dichloromethane, toluene, anisole, and mixtures thereof. The hole transport material can be present in the liquid medium in a concentration of 0.2 to 2 percent by weight. Other weight percentages of hole transport material may be used depending upon the liquid medium. The hole transport layer can be applied by any continuous or discontinuous liquid deposition technique. In one embodiment, the hole transport layer is applied by spin coating. In one embodiment, the hole transport layer is applied by ink jet printing. After liquid deposition, the liquid medium can be removed in air, in an inert atmosphere, or by vacuum, at room temperature or with heating. In one embodiment, the layer is heated to a temperature less than 275° C. In one embodiment, the heating temperature is between 170° C. and 275° C. In one embodiment, the heating temperature is between 170° C. and 200° C. In one embodiment, the heating temperature is between 190° C. and 220° C. In one embodiment, the heating temperature is between 210° C. and 240° C. In one embodiment, the heating temperature is between 230° C. and 270° C. The heating time is dependent upon the temperature, and is generally between 5 and 60 minutes. In one embodiment, the final layer thickness is between 5 and 50 nm. In one embodiment, the final layer thickness is between 5 and 15 nm. In one embodiment, the final layer thickness is between 15 and 25 nm. In one embodiment, the final layer thickness is between 25 and 35 nm. In one embodiment, the final layer thickness is between 35 and 50 nm.

The photoactive layer can be deposited from any liquid medium in which it is dissolved or dispersed and from which it will form a film. In one embodiment, the liquid medium consists essentially of one or more organic solvents. In one embodiment, the liquid medium consists essentially of water or water and an organic solvent. In one embodiment the organic solvent is an aromatic solvent. In one embodiment, the organic liquid is selected from chloroform, dichloromethane, toluene, anisole, and mixtures thereof. The photoactive material can be present in the liquid medium in a concentration of 0.2 to 2 percent by weight. Other weight percentages of photoactive material may be used depending upon the liquid medium. The photoactive layer can be applied by any continuous or discontinuous liquid deposition technique. In one embodiment, the photoactive layer is applied by spin coating. In one embodiment, the photoactive layer is applied by ink jet printing. After liquid deposition, the liquid medium can be removed in air, in an inert atmosphere, or by vacuum, at room temperature or with heating. In one embodiment, the deposited layer is heated to a temperature that is less than the Tg of the material having the lowest Tg. In one embodiment, the heating temperature is at least 10° C. less than the lowest Tg. In one embodiment, the heating temperature is at least 20° C. less than the lowest Tg. In one embodiment, the heating temperature is at least 30° C. less than the lowest Tg. In one embodiment, the heating temperature is between 50° C. and 150° C. In one embodiment, the heating temperature is between 50° C. and 75° C. In one embodiment, the heating temperature is between 75° C. and 100° C. In one embodiment, the heating temperature is between 100° C. and 125° C. In one embodiment, the heating temperature is between 125° C. and 150° C. The heating time is dependent upon the temperature, and is generally between 5 and 60 minutes. In one embodiment, the final layer thickness is between 25 and 100 nm.

In one embodiment, the final layer thickness is between 25 and 40 nm. In one embodiment, the final layer thickness is between 40 and 65 nm. In one embodiment, the final layer thickness is between 65 and 80 nm. In one embodiment, the final layer thickness is between 80 and 100 nm.

The hole blocking layer, when present, can be deposited by any vapor deposition method. In one embodiment, it is deposited by thermal evaporation under vacuum. In one embodiment, the final layer thickness is between 1 and 100 nm. In one embodiment, the final layer thickness is between 1 and 15 nm. In one embodiment, the final layer thickness is between 15 and 30 nm. In one embodiment, the final layer thickness is between 30 and 45 nm. In one embodiment, the final layer thickness is between 45 and 60 nm. In one embodiment, the final layer thickness is between 60 and 75 nm. In one embodiment, the final layer thickness is between 75 and 90 nm. In one embodiment, the final layer thickness is between 90 and 100 nm.

The electron transport layer can be deposited by any vapor deposition method. In one embodiment, it is deposited by thermal evaporation under vacuum. In one embodiment, the final layer thickness is between 1 and 100 nm. In one embodiment, the final layer thickness is between 1 and 15 nm. In one embodiment, the final layer thickness is between 15 and 30 nm. In one embodiment, the final layer thickness is between 30 and 45 nm. In one embodiment, the final layer thickness is between 45 and 60 nm. In one embodiment, the final layer thickness is between 60 and 75 nm. In one embodiment, the final layer thickness is between 75 and 90 nm. In one embodiment, the final layer thickness is between 90 and 100 nm.

The hole blocking layer, when present, can be deposited by any vapor deposition method. In one embodiment, it is deposited by thermal evaporation under vacuum. In one embodiment, the vacuum is less than 10⁻⁶ torr. In one embodiment, the vacuum is less than 10⁻⁷ torr. In one embodiment, the vacuum is less than 10⁻⁸ torr. In one embodiment, the material is heated to a temperature in the range of 100° C. to 400° C. In one embodiment, the material is heated to a temperature in the range of 100° C. to 150° C. In one embodiment, the material is heated to a temperature in the range of 150° C. to 200° C. In one embodiment, the material is heated to a temperature in the range of 200° C. to 250° C. In one embodiment, the material is heated to a temperature in the range of 250° C. to 300° C. In one embodiment, the material is heated to a temperature in the range of 300° C. to 350° C. In one embodiment, the material is heated to a temperature in the range of 350° C. to 400° C. In one embodiment, the material is deposited at a rate of 0.5 to 10 Å/sec. In one embodiment, the material is deposited at a rate of 0.5 to 1 Å/sec. In one embodiment, the material is deposited at a rate of 1 to 2 Å/sec. In one embodiment, the material is deposited at a rate of 2 to 3 Å/sec. In one embodiment, the material is deposited at a rate of 3 to 4 Å/sec. In one embodiment, the material is deposited at a rate of 4 to 5 Å/sec. In one embodiment, the material is deposited at a rate of 5 to 6 Å/sec. In one embodiment, the material is deposited at a rate of 6 to 7 Å/sec. In one embodiment, the material is deposited at a rate of 7 to 8 Å/sec. In one embodiment, the material is deposited at a rate of 8 to 9 Å/sec. In one embodiment, the material is deposited at a rate of 9 to 10 Å/sec. In one embodiment, the final layer thickness is between 0.1 and 3 nm. In one embodiment, the final layer thickness is between 0.1 and 1 nm. In one embodiment, the final layer thickness is between 1 and 2 nm. In one embodiment, the final layer thickness is between 2 and 3 nm.

The electron injection layer can be deposited by any vapor deposition method. In one embodiment, it is deposited by thermal evaporation under vacuum. In one embodiment, the vacuum is less than 10⁻⁶ torr. In one embodiment, the vacuum is less than 10⁻⁷ torr. In one embodiment, the vacuum is less than 10⁻⁸ torr. In one embodiment, the material is heated to a temperature in the range of 100° C. to 400° C. In one embodiment, the material is heated to a temperature in the range of 100° C. to 150° C. In one embodiment, the material is heated to a temperature in the range of 150° C. to 200° C. In one embodiment, the material is heated to a temperature in the range of 200° C. to 250° C. In one embodiment, the material is heated to a temperature in the range of 250° C. to 300° C. In one embodiment, the material is heated to a temperature in the range of 300° C. to 350° C. In one embodiment, the material is heated to a temperature in the range of 350° C. to 400° C. In one embodiment, the material is deposited at a rate of 0.5 to 10 Å/sec. In one embodiment, the material is deposited at a rate of 0.5 to 1 Å/sec. In one embodiment, the material is deposited at a rate of 1 to 2 Å/sec. In one embodiment, the material is deposited at a rate of 2 to 3 Å/sec. In one embodiment, the material is deposited at a rate of 3 to 4 Å/sec. In one embodiment, the material is deposited at a rate of 4 to 5 Å/sec. In one embodiment, the material is deposited at a rate of 5 to 6 Å/sec. In one embodiment, the material is deposited at a rate of 6 to 7 Å/sec. In one embodiment, the material is deposited at a rate of 7 to 8 Å/sec. In one embodiment, the material is deposited at a rate of 8 to 9 Å/sec. In one embodiment, the material is deposited at a rate of 9 to 10 Å/sec. In one embodiment, the final layer thickness is between 0.1 and 3 nm. In one embodiment, the final layer thickness is between 0.1 and 1 nm. In one embodiment, the final layer thickness is between 1 and 2 nm. In one embodiment, the final layer thickness is between 2 and 3 nm.

The cathode can be deposited by any vapor deposition method. In one embodiment, it is deposited by thermal evaporation under vacuum. In one embodiment, the vacuum is less than 10⁻⁶ torr. In one embodiment, the vacuum is less than 10⁻⁷ torr. In one embodiment, the vacuum is less than 10⁻⁸ torr. I n one embodiment, the vacuum is less than 10⁻⁶ torr. In one embodiment, the vacuum is less than 10⁻⁷ torr. In one embodiment, the vacuum is less than 10⁻⁸ torr. In one embodiment, the material is heated to a temperature in the range of 100° C. to 400° C. In one embodiment, the material is heated to a temperature in the range of 100° C. to 150° C. In one embodiment, the material is heated to a temperature in the range of 150° C. to 200° C. In one embodiment, the material is heated to a temperature in the range of 200° C. to 250° C. In one embodiment, the material is heated to a temperature in the range of 250° C. to 300° C. In one embodiment, the material is heated to a temperature in the range of 300° C. to 350° C. In one embodiment, the material is heated to a temperature in the range of 350° C. to 400° C. In one embodiment, the material is deposited at a rate of 0.5 to 10 Å/sec. In one embodiment, the material is deposited at a rate of 0.5 to 1 Å/sec. In one embodiment, the material is deposited at a rate of 1 to 2 Å/sec. In one embodiment, the material is deposited at a rate of 2 to 3 Å/sec. In one embodiment, the material is deposited at a rate of 3 to 4 Å/sec. In one embodiment, the material is deposited at a rate of 4 to 5 Å/sec. In one embodiment, the material is deposited at a rate of 5 to 6 Å/sec. In one embodiment, the material is deposited at a rate of 6 to 7 Å/sec. In one embodiment, the material is deposited at a rate of 7 to 8 Å/sec. In one embodiment, the material is deposited at a rate of 8 to 9 Å/sec. In one embodiment, the material is deposited at a rate of 9 to 10 Å/sec. In one embodiment, the final layer thickness is between 10 and 10000 nm. In one embodiment, the final layer thickness is between 10 and 1000 nm. In one embodiment, the final layer thickness is between 10 and 50 nm. In one embodiment, the final layer thickness is between 50 and 100 nm. In one embodiment, the final layer thickness is between 100 and 200 nm. In one embodiment, the final layer thickness is between 200 and 300 nm. In one embodiment, the final layer thickness is between 300 and 400 nm. In one embodiment, the final layer thickness is between 400 and 500 nm. In one embodiment, the final layer thickness is between 500 and 600 nm. In one embodiment, the final layer thickness is between 600 and 700 nm. In one embodiment, the final layer thickness is between 700 and 800 nm. In one embodiment, the final layer thickness is between 800 and 900 nm. In one embodiment, the final layer thickness is between 900 and 1000 nm. In one embodiment, the final layer thickness is between 1000 and 2000 nm. In one embodiment, the final layer thickness is between 2000 and 3000 nm. In one embodiment, the final layer thickness is between 3000 and 4000 nm. In one embodiment, the final layer thickness is between 4000 and 5000 nm. In one embodiment, the final layer thickness is between 5000 and 6000 nm. In one embodiment, the final layer thickness is between 6000 and 7000 nm. In one embodiment, the final layer thickness is between 7000 and 8000 nm. In one embodiment, the final layer thickness is between 8000 and 9000 nm. In one embodiment, the final layer thickness is between 9000 and 10000 nm.

In one embodiment, the device is fabricated by vapor deposition of the buffer layer, the hole transport layer, and the photoactive layer, the hole blocking layer, when present, the electron transport layer, the electron injection layer, and the cathode.

In one embodiment, the buffer layer is applied by vapor deposition. In one embodiment, it is deposited by thermal evaporation under vacuum. In one embodiment, the vacuum is less than 10⁻⁶ torr. In one embodiment, the vacuum is less than 10⁻⁷ torr. In one embodiment, the vacuum is less than 10⁻⁸ torr. In one embodiment, the material is heated to a temperature in the range of 100° C. to 400° C. In one embodiment, the material is heated to a temperature in the range of 100° C. to 150° C. In one embodiment, the material is heated to a temperature in the range of 150° C. to 200° C. In one embodiment, the material is heated to a temperature in the range of 200° C. to 250° C. In one embodiment, the material is heated to a temperature in the range of 250° C. to 300° C. In one embodiment, the material is heated to a temperature in the range of 300° C. to 350° C. In one embodiment, the material is heated to a temperature in the range of 350° C. to 400° C. In one embodiment, the material is deposited at a rate of 0.5 to 10 Å/sec. In one embodiment, the material is deposited at a rate of 0.5 to 1 Å/sec. In one embodiment, the material is deposited at a rate of 1 to 2 Å/sec. In one embodiment, the material is deposited at a rate of 2 to 3 Å/sec. In one embodiment, the material is deposited at a rate of 3 to 4 Å/sec. In one embodiment, the material is deposited at a rate of 4 to 5 Å/sec. In one embodiment, the material is deposited at a rate of 5 to 6 Å/sec. In one embodiment, the material is deposited at a rate of 6 to 7 Å/sec. In one embodiment, the material is deposited at a rate of 7 to 8 Å/sec. In one embodiment, the material is deposited at a rate of 8 to 9 Å/sec. In one embodiment, the material is deposited at a rate of 9 to 10 Å/sec. In one embodiment, the final layer thickness is between 5 and 200 nm. In one embodiment, the final layer thickness is between 5 and 30 nm. In one embodiment, the final layer thickness is between 30 and 60 nm. In one embodiment, the final layer thickness is between 60 and 90 nm. In one embodiment, the final layer thickness is between 90 and 120 nm. In one embodiment, the final layer thickness is between 120 and 150 nm. In one embodiment, the final layer thickness is between 150 and 280 nm. In one embodiment, the final layer thickness is between 180 and 200 nm.

In one embodiment, the hole transport layer is applied by vapor deposition. In one embodiment, it is deposited by thermal evaporation under vacuum. In one embodiment, the vacuum is less than 10⁻⁶ torr. In one embodiment, the vacuum is less than 10⁻⁷ torr. In one embodiment, the vacuum is less than 10 ⁻⁸ torr. In one embodiment, the vacuum is less than 10⁻⁶ torr. In one embodiment, the vacuum is less than 10⁻⁷ torr. In one embodiment, the vacuum is less than 10° torr. In one embodiment, the material is heated to a temperature in the range of 100° C. to 400° C. In one embodiment, the material is heated to a temperature in the range of 100° C. to 150° C. In one embodiment, the material is heated to a temperature in the range of 150° C. to 200° C. In one embodiment, the material is heated to a temperature in the range of 200° C. to 250° C. In one embodiment, the material is heated to a temperature in the range of 250° C. to 300° C. In one embodiment, the material is heated to a temperature in the range of 300° C. to 350° C. In one embodiment, the material is heated to a temperature in the range of 350° C. to 400° C. In one embodiment, the material is deposited at a rate of 0.5 to 10 Å/sec. In one embodiment, the material is deposited at a rate of 0.5 to 1 Å/sec. In one embodiment, the material is deposited at a rate of 1 to 2 Å/sec. In one embodiment, the material is deposited at a rate of 2 to 3 Å/sec. In one embodiment, the material is deposited at a rate of 3 to 4 Å/sec. In one embodiment, the material is deposited at a rate of 4 to 5 Å/sec. In one embodiment, the material is deposited at a rate of 5 to 6 Å/sec. In one embodiment, the material is deposited at a rate of 6 to 7 Å/sec. In one embodiment, the material is deposited at a rate of 7 to 8 Å/sec. In one embodiment, the material is deposited at a rate of 8 to 9 Å/sec. In one embodiment, the material is deposited at a rate of 9 to 10 Å/sec. In one embodiment, the final layer thickness is between 5 and 200 nm. In one embodiment, the final layer thickness is between 5 and 30 nm. In one embodiment, the final layer thickness is between 30 and 60 nm. In one embodiment, the final layer thickness is between 60 and 90 nm. In one embodiment, the final layer thickness is between 90 and 120 nm. In one embodiment, the final layer thickness is between 120 and 150 nm. In one embodiment, the final layer thickness is between 150 and 280 nm. In one embodiment, the final layer thickness is between 180 and 200 nm.

In one embodiment, the photoactive layer is applied by vapor deposition. In one embodiment, it is deposited by thermal evaporation under vacuum. In one embodiment, the photoactive layer consists essentially of a single electroluminescent compound, which is deposited by thermal evaporation under vacuum. In one embodiment, the vacuum is less than 10⁻⁶ torr. In one embodiment, the vacuum is less than 10⁻⁷ torr. In one embodiment, the vacuum is less than 10⁻⁸ torr. In one embodiment, the vacuum is less than 10⁻⁶ torr. In one embodiment, the vacuum is less than 10⁻⁷ torr. In one embodiment, the vacuum is less than 10⁻⁸ torr. In one embodiment, the material is heated to a temperature in the range of 100° C. to 400° C. In one embodiment, the material is heated to a temperature in the range of 100° C. to 150° C. In one embodiment, the material is heated to a temperature in the range of 150° C. to 200° C. In one embodiment, the material is heated to a temperature in the range of 200° C. to 250° C. In one embodiment, the material is heated to a temperature in the range of 250° C. to 300° C. In one embodiment, the material is heated to a temperature in the range of 300° C. to 350° C. In one embodiment, the material is heated to a temperature in the range of 350° C. to 400° C. In one embodiment, the material is deposited at a rate of 0.5 to 10 Å/sec. In one embodiment, the material is deposited at a rate of 0.5 to 1 Å/sec. In one embodiment, the material is deposited at a rate of 1 to 2 Å/sec. In one embodiment, the material is deposited at a rate of 2 to 3 Å/sec. In one embodiment, the material is deposited at a rate of 3 to 4 Å/sec. In one embodiment, the material is deposited at a rate of 4 to 5 Å/sec. In one embodiment, the material is deposited at a rate of 5 to 6 Å/sec. In one embodiment, the material is deposited at a rate of 6 to 7 Å/sec. In one embodiment, the material is deposited at a rate of 7 to 8 Å/sec. In one embodiment, the material is deposited at a rate of 8 to 9 Å/sec. In one embodiment, the material is deposited at a rate of 9 to 10 Å/sec. In one embodiment, the final layer thickness is between 5 and 200 nm. In one embodiment, the final layer thickness is between 5 and 30 nm. In one embodiment, the final layer thickness is between 30 and 60 nm. In one embodiment, the final layer thickness is between 60 and 90 nm. In one embodiment, the final layer thickness is between 90 and 120 nm. In one embodiment, the final layer thickness is between 120 and 150 nm. In one embodiment, the final layer thickness is between 150 and 280 nm. In one embodiment, the final layer thickness is between 180 and 200 nm.

In one embodiment, the photoactive layer comprises two electroluminescent materials, each of which is applied by thermal evaporation under vacuum. Any of the above listed vacuum conditions and temperatures can be used. Any of the above listed deposition rates can be used. The relative deposition rates can be from 50:1 to 1:50. In one embodiment, the relative deposition rates are from 1:1 to 1:3. In one embodiment, the relative deposition rates are from 1:3 to 1:5. In one embodiment, the relative deposition rates are from 1:5 to 1:8. In one embodiment, the relative deposition rates are from 1:8 to 1:10. In one embodiment, the relative deposition rates are from 1:10 to 1:20. In one embodiment, the relative deposition rates are from 1:20 to 1:30. In one embodiment, the relative deposition rates are from 1:30 to 1:50. The total thickness of the layer can be the same as that described above for a single-component photoactive layer.

In one embodiment, the photoactive layer comprises one electroluminescent material and at least one host material, each of which is applied by thermal evaporation under vacuum. Any of the above listed vacuum conditions and temperatures can be used. Any of the above listed deposition rates can be used. The relative deposition rate of electroluminescent material to host can be from 1:1 to 1:99. In one embodiment, the relative deposition rates are from 1:1 to 1:3. In one embodiment, the relative deposition rates are from 1:3 to 1:5. In one embodiment, the relative deposition rates are from 1:5 to 1:8. In one embodiment, the relative deposition rates are from 1:8 to 1:10. In one embodiment, the relative deposition rates are from 1:10 to 1:20. In one embodiment, the relative deposition rates are from 1:20 to 1:30. In one embodiment, the relative deposition rates are from 1:30 to 1:40. In one embodiment, the relative deposition rates are from 1:40 to 1:50. In one embodiment, the relative deposition rates are from 1:50 to 1:60. In one embodiment, the relative deposition rates are from 1:60 to 1:70. In one embodiment, the relative deposition rates are from 1:70 to 1:80. In one embodiment, the relative deposition rates are from 1:80 to 1:90. In one embodiment, the relative deposition rates are from 1:90 to 1:99. The total thickness of the layer can be the same as that described above for a single-component photoactive layer.

In one embodiment, the hole blocking layer, when present, is applied by vapor deposition. In one embodiment, it is deposited by thermal evaporation under vacuum. In one embodiment, the vacuum is less than 10⁻⁶ torr. In one embodiment, the vacuum is less than 10⁻⁷ torr. In one embodiment, the vacuum is less than 10⁻⁸ torr. In one embodiment, the material is heated to a temperature in the range of 100° C. to 400° C. In one embodiment, the material is heated to a temperature in the range of 100° C. to 150° C. In one embodiment, the material is heated to a temperature in the range of 150° C. to 200° C. In one embodiment, the material is heated to a temperature in the range of 200° C. to 250° C. In one embodiment, the material is heated to a temperature in the range of 250° C. to 300° C. In one embodiment, the material is heated to a temperature in the range of 300° C. to 350° C. In one embodiment, the material is heated to a temperature in the range of 350° C. to 400° C. In one embodiment, the material is deposited at a rate of 0.5 to 10 Å/sec. In one embodiment, the material is deposited at a rate of 0.5 to 1 Å/sec. In one embodiment, the material is deposited at a rate of 1 to 2 Å/sec. In one embodiment, the material is deposited at a rate of 2 to 3 Å/sec. In one embodiment, the material is deposited at a rate of 3 to 4 Å/sec. In one embodiment, the material is deposited at a rate of 4 to 5 Å/sec. In one embodiment, the material is deposited at a rate of 5 to 6 Å/sec. In one embodiment, the material is deposited at a rate of 6 to 7 Å/sec. In one embodiment, the material is deposited at a rate of 7 to 8 Å/sec. In one embodiment, the material is deposited at a rate of 8 to 9 Å/sec. In one embodiment, the material is deposited at a rate of 9 to 10 Å/sec. In one embodiment, the final layer thickness is between 5 and 200 nm. In one embodiment, the final layer thickness is between 5 and 30 nm. In one embodiment, the final layer thickness is between 30 and 60 nm. In one embodiment, the final layer thickness is between 60 and 90 nm. In one embodiment, the final layer thickness is between 90 and 120 nm. In one embodiment, the final layer thickness is between 120 and 150 nm. In one embodiment, the final layer thickness is between 150 and 280 nm. In one embodiment, the final layer thickness is between 180 and 200 nm.

In one embodiment, the electron transport layer is applied by vapor deposition. In one embodiment, it is deposited by thermal evaporation under vacuum. In one embodiment, the vacuum is less than 10⁻⁶ torr. In one embodiment, the vacuum is less than 10⁻⁷ torr. In one embodiment, the vacuum is less than 10⁻⁸ torr. In one embodiment, the material is heated to a temperature in the range of 100° C. to 400° C. In one embodiment, the material is heated to a temperature in the range of 100° C. to 150° C. In one embodiment, the material is heated to a temperature in the range of 150° C. to 200° C. In one embodiment, the material is heated to a temperature in the range of 200° C. to 250° C. In one embodiment, the material is heated to a temperature in the range of 250° C. to 300° C. In one embodiment, the material is heated to a temperature in the range of 300° C. to 350° C. In one embodiment, the material is heated to a temperature in the range of 350° C. to 400° C. In one embodiment, the material is deposited at a rate of 0.5 to 10 Å/sec. In one embodiment, the material is deposited at a rate of 0.5 to 1 Å/sec. In one embodiment, the material is deposited at a rate of 1 to 2 Å/sec. In one embodiment, the material is deposited at a rate of 2 to 3 Å/sec. In one embodiment, the material is deposited at a rate of 3 to 4 Å/sec. In one embodiment, the material is deposited at a rate of 4 to 5 Å/sec. In one embodiment, the material is deposited at a rate of 5 to 6 Å/sec. In one embodiment, the material is deposited at a rate of 6 to 7 Å/sec. In one embodiment, the material is deposited at a rate of 7 to 8 Å/sec. In one embodiment, the material is deposited at a rate of 8 to 9 Å/sec. In one embodiment, the material is deposited at a rate of 9 to 10 Å/sec. In one embodiment, the final layer thickness is between 5 and 200 nm. In one embodiment, the final layer thickness is between 5 and 30 nm. In one embodiment, the final layer thickness is between 30 and 60 nm. In one embodiment, the final layer thickness is between 60 and 90 nm. In one embodiment, the final layer thickness is between 90 and 120 nm. In one embodiment, the final layer thickness is between 120 and 150 nm. In one embodiment, the final layer thickness is between 150 and 280 nm. In one embodiment, the final layer thickness is between 180 and 200 nm.

In one embodiment, the electron injection layer is applied by vapor deposition, as described above.

In one embodiment, the cathode is applied by vapor deposition, as describe above.

In one embodiment, the device is fabricated by vapor deposition of some of the organic layers, and liquid deposition of some of the organic layers. In one embodiment, the device is fabricated by liquid deposition of the buffer layer, and vapor deposition of all of the other layers.

Other features and benefits of any one or more of the embodiments will be apparent from the following detailed description, and from the claims. Before addressing details of embodiments described below, some terms are defined or clarified.

The term “organic electronic device” is intended to mean a device including one or more semiconductor layers or materials. Organic electronic devices include, but are not limited to: (1) devices that convert electrical energy into radiation (e.g., a light-emitting diode, light emitting diode display, diode laser, or lighting panel), (2) devices that detect signals through electronic processes (e.g., photodetectors photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode). The term device also includes coating materials for memory storage devices, antistatic films, biosensors, electrochromic devices, solid electrolyte capacitors, energy storage devices such as a rechargeable battery, and electromagnetic shielding applications.

The term “hydroxyaryl-N-heterocycle” is intended to mean a ligand derived from a compound having at least one nitrogen-containing heterocyclic group and at least one aromatic group with a hydroxyl substitutent, where the O of the hydroxyl group and the N of the heterocyclic ring can coordinate to a metal to form a 5- or 6-membered ring. The N-heterocyclic group and the hydroxy-substituted aromatic group can be joined with a single bond or fused together. The N-heterocyclic group and the hydroxy-substituted aromatic group can each comprise a single ring or two or more fused rings.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components of the invention. This is done merely for convenience and to give a general sense of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### EXAMPLES

The concepts described herein will be further described in the following examples, which do not limit the scope of the invention described in the claims.

### Example 1A

A sample of 101.67 g aqueous polypyrrole (Aldrich catalog #482552, 5% by mass in water) was mixed with 101.67 g deionized water. After mixing, 13.15 g AMBERLYST 15 acidic cation exchange resin from Aldrich Company was added and placed on a twin roller for one hour. The resin mixture was then filtered with a filter paper. To the filtrate, 12.2 g of fresh AMBERLYST 15 acid resin was added and stirred for one hour on the twin roller. The resin mixture was filtered to remove the resin and then mixed with 15 g DOWEX 550 Å, a hydroxide anion-exchange resin from Aldrich. This resin mixture was stirred on the twin roller for one and half hour and then filtered to remove the resin. To the filtrate, 50.1 g deionized water and 20.0 g AMBERLYST resin was added and stirred on the twin roller overnight. The resin mixture was filtered. The filtrate weighed 185 g.

An 87 g sample of the filtrate was kept and measured for pH, which was 1.5.

The sample was added with 1M NaOH solution to reach pH of 3.9. The pH was found stable over time. The pH 1.5 and 3.9 samples were measured for conductivity by depositing on ITO substrates. After depositing, the deposited samples were baked at 130° C. in air for 10 minutes. Conductivity of deposited pH 1.5 and 3.9 samples are 1.3×10⁻⁴S/cm, and 1.8×10⁻⁵S/cm, respectively, and are listed in TABLE 1.

### Example 1B

Baytron-P VPAI4083, an aqueous poly(3,4-ethyenedioxythiophene) dispersion having poly(styrenesulfonic acid) as counter anions, was purchased from H. C. Starck. The pH of as-received poly(3,4-ethyenedioxythiophene) poly(styrenesulfonate) aqueous dispersion was 1.7. Two 100 g samples were added with 1M NaOH solution to achieve a pH of 1.9 and 3, respectively. Conductivity is shown in TABLE 1. Particle size data was measured by using AccuSizer Model 780A (Particle Sizing Systems, Santa Barbara, Calif.). The measurement shows the number of particles within each range of particle size that is present in one mL dispersion.

### Example 1C

Baytron-P VPAI4083 of a different batch from the one in Example 1B was used in this example. The pH of the poly(3,4-ethyenedioxythiophene) poly(styrenesulfonate) aqueous dispersion was 1.72. Two 100 g samples were added with 1 M concentration of tetra-methyl ammonium hydroxide solution to achieve a pH of 3.97 and 6.93, respectively.

The conductivity data is summarized in TABLE 1. The conductivities are suitable for use in an organic electronic device in a hole transport layer. Particle size data was measured by an AccuSizer Model 780A (Particle Sizing Systems, Santa Barbara, Calif.).

TABLE 1

| | | | Particle #/mL | | |
|---|---|---|---|---|---|
| | Sample | Conductivity | | # ≧ | # ≧ |
| Ex. | pH | (S/cm) | ≧0.75 μm | 1.51 μm | 2.46 μm |
| 1A | 1.5 | 1.3 × 10⁻⁴ | — | — | — |
| 1A | 3.9 | 1.8 × 10⁻⁵ | — | — | — |
| 1B | 1.7 | ~1 × 10⁻³ | 271,302 | 10,577 | 8,835 |
| 1B | 1.9 | 1.1 × 10⁻³ | 240,065 | 12,324 | 8,441 |
| 1B | 3.0 | 9.4 × 10⁻³ | 203,817 | 5,007 | 2,482 |
| 1C | 1.72 | 7.4 ± 0.29 × 10⁻⁴ | 719,205 | 70,550 | 67,110 |
| 1C | 3.97 | 3.0 ± 0.40 × 10⁻⁵ | 390,712 | 40,698 | 37,281 |
| 1C | 6.93 | 2.4 ± 0.42 × 10⁻⁵ | 451,437 | 64,325 | 60,959 |

### Example 2A

Organic electronic devices (PLEDs in this example) were made having the following configuration: ITO (indium tin oxide—anode)/ECP layer/LEP (light emitting polymer)/Ba (EIL (electron injecting (hole blocking) layer))/Al(cathode). Device fabrication was made as follows. ITO/glass pieces were patterned to produce 0.25 cm² light emitting active areas. The patterned ITO/glass pieces were UV/ozone treated before use.

The pH 1.5 and 3.9 aqueous polypyrrole samples from Example 1A were spin-coated onto ITO to form a ECP layer. The electrical lead areas were then wiped cleaned with damp swabs before baked at 200° C. in air for 5 minutes. Nominal thickness of the ECP was 100 nm.

The ECP containing layer pieces were then transferred to a nitrogen-filled dry box and then top-coated with BP209, a blue LEP (light emitting polymer from Dow Chemicals Company, Midland, Mich.) using 0.9% (w/v) solution in xylene. Electrical contact areas were then wiped clean with xylene before being baked at 130° C. on a hot plate in dry box for 10 minute. Nominal thickness of the layer was 75 nm.

The ECP and LEP containing substrates were then masked and placed in a vacuum chamber. After pumping the chamber to a base pressure of 2×10⁻⁷ torr, a layer of barium was deposited to a thickness of 3 nm to form an electron injection layer. A subsequent layer of aluminum was deposited to a thickness of 400 nm, which functions as the cathode.

The chamber was then vented and the devices were then encapsulated with a glass lid and an UV curable epoxy. The devices were then measured for current/voltage and brightness. The calculated data is summarized in TABLE 2, below. The data shows that device voltage increases and the efficiency decreases with pH. It is understood that generally one seeks to decrease voltage and increase efficiency to prolong device life.

### Example 2B

PLEDs were formed having ITO/ECP/LEP/Ba/Al layers. The polymers prepared in Example 1B were used for the ECP layer. The baking conditions and thickness were similar to those described in Example 2A, except the LEP layer was prepared from a 1.0% solution of CR-01 in toluene. CR01 is a red, polymeric emitter (Covion Company in Frankfurt, Germany). The layer was baked at 130° C. on a hot plate in dry box for 10 minutes. The nominal thickness of the layer was 75 nm.

The devices were measured for current/voltage and brightness. The data is summarized in TABLE 2. The data shows that device voltage increases and the efficiency decreases with pH.

### Example 3A

PLEDs were formed having ITO/ECP/HTL(hole-transport layer)/LEP/Ba/Al layers to determine the effect of the hole-transport layer. The pH 1.5 and 3.9 polypyrrole samples from Example 1A and HT-A a hole transport material were used. All the procedures of Example 2A were followed, except an HTL layer was added between the ECP and LEP layers.

The HTL was prepared by depositing a 0.4% (w/v) solution of HT-A in toluene. The coated HTL was then wiped clean with toluene at the electrical contact lead area and then baked at 200° C. for 10 minutes on a hot plate in a dry nitrogen filled dry box. Nominal thickness of the HTL was 10 nm.

The devices were fabricated and tested according to the procedures described in Example 2A. The data is summarized in TABLE 2. The devices show surprisingly improved device efficiency and reduced device voltage.

Example 3B

PLEDs in this example have ECP formed with the pH 1.7, 1.9 and 3.0 polymers, respectively from Example 1B, and HT-A as the HTL. All the procedures in Example 2B were followed except the addition of a HTL layer between ECP and LEP.

The HTL was processed by depositing of a 0.4% (w/v) solution of HT-A in toluene. The coated HTL was then wiped clean with toluene at the electrical contact lead area and then baked at 200° C. for 10 minutes on a hot plate in a nitrogen filled dry box. The nominal thickness of the HTL was 10 nm. The devices were fabricated and tested at the same time as those in Example 2B. The data is summarized in TABLE 2. The data shows that incorporation of a HTL has greatly improved device efficiency and reduced device voltage. The device function with incorporation of the HTL is also shown to be much less affected by pH increases from 1.7 to 3.0.

TABLE 2

| Ex. | PH | HTM | Efficiency (Cd/A) | Voltage (Volt) |
|---|---|---|---|---|
| 2A | 1.5 | — | 1.8 | 5.5 |
| 3A | 1.5 | HT-A | 6.0 | 4.8 |
| 2A | 3.9 | — | 0.4 | 7.5 |
| 3A | 3.9 | HT-A | 4.5 | 5.0 |
| 2B | 1.7 | — | 1.4 | 5.0 |
| 3B | 1.7 | HT-A | 1.7 | 4.7 |
| 2B | 1.9 | — | 1.3 | 4.4 |
| 3B | 1.9 | HT-A | 1.9 | 4.4 |
| 2B | 3.0 | — | 0.4 | 6.6 |
| 3B | 3.0 | HT-A | 1.5 | 5.5 |

### Example 4A

The organic electronic device has the configuration: ITO/ECP/SME (small molecule emitting material)/HBL/ETL/EIL/AI. The device was fabricated as follows. Patterned ITO/glass pieces purchased from Thin Film Device Company, having the dimensions 35 mm×45 mm and four active areas (also called pixels) of 2.25 mm×2.25 mm, were UV/ozone treated for 5 minutes. Two pieces of the substrate were used for each sample summarized in TABLE 3.

Samples from Example 1C were deposited onto ITO (140 nm thick)/glass to form a ECP layer.

The ECP containing layer pieces were transferred to a nitrogen-filled dry box and then top-coated with an SME emitter, [bis-(2-phenyl-3-methyl-quinolinato)iridium-2,4-(5-ethyl-nonane)dione], in a host of m-bis(carbazolyl)benzene (mCP).

The substrates were then masked and placed in a vacuum chamber. A layer of BAIq (Sensient Company) was deposited via thermal evaporation to form a HBL (hole blocking layer). To the HBL, AIQ (Sensient Company) was deposited to form an ETL (electron transporting layer). Subsequently, a layer of LiF was deposited to function as electron injection layer (ETL). To the ETL, a layer of aluminum was deposited by thermal evaporation to function as the cathode. The devices were then encapsulated using a glass lid and UV curable epoxy.

These devices were measured for current/voltage and brightness. The data of each first three sample are summarized in TABLE 3. The data clearly shows that the ECPs have similar maximum efficiency, maximum luminance, and efficiency and voltage at 450 luminance. The pH 3.97 sample seems to perform better than pH 1.72 and 6.93. The device data is a result of an average of 8 pixels for each sample.

### Example 4B

Devices similar to those of Example 4 Å were made for the pH 6.93 sample was combined with divinyl p-TPD, a hole transporting material To make Divinyl p-TPD, 4-Bromostyrene (10.16 g, 55.5 mmol) was added dropwise to a mixture of diphenylbezidine (6.22 g, 18.5 mmol), NaO-tBu (5.33 g, 55.5 mmol), Pd₂(dba)₃ (0.85 g, 0.925 mmol) and P(tBu)₃ (0.19 g, 0.925 mmol) in toluene (250 mL) and stirred for 22 hours. The resulting mixture was filtered through celite and silica and the solvent was evaporated to obtain a dark viscous material. The dark viscous material was purified by precipitation into methanol from dichloromethane. The resulting material was purified using chromatography (dichloromethane/hexanes 1/4) to yield a pale yellow powder (2.63 g, 26%). 1H NMR (CD2Cl2, 500 MHz) 7.48 (4H, d, J=8.6 Hz, Ar—H), 7.32 (4H, d, J=8.5 Hz, Ar—H), 7.28 (4H, t, J=7.8 Hz, Ar—H), 7.13-7.11 (8H, m, Ar—H), 7.07-7.04 (6H, m, Ar—H), 6.69 (2H, dd, J=17.6, 11.3 Hz, ═CH), 5.66 (2H, dd, J=17.6, 0.8 Hz, ═CH2 (cis)), 5.17 (2H, d, J=11.3 Hz, ═CH2 (trans)).

The procedures described in Example 4A were followed except the addition of a layer between ECP and SME.

A layer was processed by spin-coating divinyl p-TPD on top of the ECP made from the pH 6.93 sample. The coated HTL was then heated to remove solvent and to allow the crosslinking of vinyl groups between divinyl p-TPD.

The device was tested at the same time as those devices in Example 4A. The data is summarized in TABLE 3. The data shows that incorporation of HTL has greatly improved device efficiency at maximum luminance and 450 luminance.

TABLE 3

| | | | | | | Efficiency |
|---|---|---|---|---|---|---|
| | | | Efficiency | Luminance | V@450 | @450 |
| | | | (max.) | (max.) | Lum. | Lum. |
| Ex. | pH | HTM | (Cd/A) | (Cd/m2) | (Volt) | (Cd/A) |
| 4A | 1.72 | — | 4.8 | 4,541 | 11.1 | 4.4 |
| 4A | 3.97 | — | 6.2 | 4,487 | 12.1 | 5.6 |
| 4A | 6.93 | — | 4.4 | 3,644 | 12.7 | 4.2 |
| 4B | 6.93 | Divinyl | 14.1 | 5,457 | 11.4 | 8.8 |
| | | p-TPD | | | | |

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed:

1. An organic electronic device comprising a layer of an electrically conductive polymer deposited from a composition having a pH greater than 2.0, superposed on which is a layer of a hole transport material, wherein the hole transport material is a different material than the electrically conductive polymer.

2. The organic electronic device of claim 1 wherein the electrically conductive polymer is electrically conductive or semi-conductive.

3. The organic electronic device of claim 1 wherein the electrically conductive polymer is doped with a water soluble non-fluorinated acid.

4. The organic electronic device of claim 1 wherein the electrically conductive polymer comprises a polythiophene, a polypyrrole, a polyaniline, a polycyclic aromatic polymer, a copolymer thereof, or a mixture thereof.

5. The organic electronic device of claim 1 wherein the electrically conductive polymer comprises polydioxythiophene, polyaniline, polypyrrole, poly(thienothiophene), a co-polymer thereof, or a mixture thereof.

6. The organic electronic device of claim 1 wherein the electrically conductive polymer composition comprises a poly(3,4-ethyenedioxythiophene) and a poly(styrenesulfonate).

7. The organic electronic device of claim 1 wherein the electrically conductive polymer composition comprises a polyaniline and a poly(styrenesulfonate).

8. The organic electronic device of claim 1 wherein the electrically conductive polymer composition comprises a poly(thienothiophene) and a poly(styrenesulfonate).

9. The organic electronic device of claim 1 wherein the electrically conductive polymer composition comprises a polypyrrole.

10. The organic electronic device of claim 1 wherein the electrically conductive polymer composition is deposited from a composition having a pH greater than 3.0.

11. The organic electronic device of claim 1 wherein the electrically conductive polymer composition is deposited from a composition having a pH greater than 3.9.

12. The organic electronic device of claim 1 wherein the hole transport material comprises N,N′diphenyl-N,N′-bis(3-methylphenyl)-[1,1′-biphenyl]-4,4′-diamine (TPD), N,N′-diphenyl-N,N′-bis(4-vinylphenyl)-[1,1′-biphenyl]-4,4′-diamine (divinyl p-TPD), 1,1bis[(di-4-tolylamino)phenyl]cyclohexane (TAPC), N,N′bis(4-methylphenyl)-N,N′-bis(4-ethylphenyl)-[1,1′-(3,3′-dimethyl)biphenyl-]-4,4′-diamine (ETPD), tetrakis (3-methylphenyl)-N,N,N′,N′-2,5-phenylenediamine (PDA), a-phenyl 4-N,N-diphenylaminostyrene (TPS), p(diethylamino)benzaldehyde diphenylhydrazone (DEH), triphenylamine (TPA), bis[4(N,N-diethylamino)-2-methylphenyl](4-methylphenyl)methane (MPMP), 1phenyl-3-[p-(diethylamino)styryl]-5-[p-(diethylamino)phenyl]pyrazoline (PPR or DEASP), 1,2trans-bis(9H-carbazol-9-yl)cyclobutane (DCZB), N,N,N′,N′tetrakis(4-methylphenyl)-(1,1′-biphenyl)-4,4′-diamine (TTB), N,N′-Bis(naphthalen-1-yl)-N,N′-bis-(phenyl)benzidine (.alpha.-NPB), porphyrinic compounds, polyvinylcarbazole, (phenylmethyl)polysilane, or poly(arylamines).

13. The organic electronic device of claim 12 wherein the hole transport material comprises N,N′-diphenyl-N,N′-bis(4-vinylphenyl)-[1,1′-biphenyl]-4,4′-diamine (divinyl-p-TPD)

14. The organic electronic device of claim 1 wherein the hole transport material comprises a fluorene-arylene copolymer, or a copolymer of arylamine with a conjugated monomer.

15. The organic electronic device of claim 12 wherein the hole transport material has a crosslinkable segment.

16. The organic electronic device of claim 1, further comprising an organic electroluminescent material superposed on the layer of hole transport material.

17. The organic electronic device of claim 16 wherein the organic electroluminescent material comprises a light emitting polymer.

18. The organic electronic device of claim 16 wherein the organic electroluminescent material comprises a small molecule emitting material.

19. A display device comprising the organic electronic device of claim 1.
